(19) United States
(12) Patent Application Publication
(10) Pub. No.: US 2008/0137442 A1
(43) Pub. Date: Jun. 12, 2008

(54) Memory data reading circuit

(75) Inventors: Yen-Wen Chen, Taipei County (TW); Yen-Ynn Chou, Taipei County (TW)

Correspondence Address: Joe McKinney Muncy, PO Box 1364, Fairfax, VA, 22038-1364, US

(73) Assignee: PRINCETON TECHNOLOGY CORPORATION

(21) Appl. No.: 11/802,698

(22) Filed: May 24, 2007

(30) Foreign Application Priority Data
Dec. 6, 2006 (TW) 095145334

(51) Int. Cl. G11C 7/10

(52) U.S. Cl. 365/189.05; 365/203

(57) ABSTRACT

A data read circuit for a memory without a complex pre-charge circuit is provided. A diode is coupled between a pair of bit lines to replace the pre-charge circuit. A voltage drop caused by the diode is substantially half the operating voltage of the memory.

### BACKGROUND OF THE INVENTION

1. Field of the Invention

The invention relates to a memory data reading circuit, and more particularly to a memory data reading circuit without a precharging circuit.

2. Description of the Related Art

In a conventional memory data reading circuit, a precharging circuit precharges a bit line coupled to a desired memory cell to increase the read speed of the memory. FIG. 1 shows a conventional memory data reading circuit with a precharging circuit. In FIG. 1, the amplifier determines the data stored in the memory cell based on the voltage difference between the bit lines BL and B̅L̅. Typically, if the operating voltage of the memory is VDD, the precharging circuit 10 precharges the voltage of the bit lines BL and B̅L̅ to ½ VDD to acquire an optimal operating point. Thus, the precharging circuit 10 is operable to provide a voltage of ½ VDD. Because memory data reading circuit designs demand continually lower operating voltage, a precharging circuit capable of stable and robust precharging voltage is desirable.

### BRIEF SUMMARY OF THE INVENTION

The invention provides memory data reading circuits. An exemplary embodiment of a memory data reading circuit of the invention comprises a first bit line, a second bit line, an amplifier, a first switch, a second switch, a data storage unit, a world line, a first transistor and a second transistor. The first switch is coupled to the first bit line and the second switch is coupled to the second bit line. The amplifier comprises a first input terminal coupled to the first bit line, a second input terminal coupled to the second bit line and an output terminal. The output terminal outputs data based on the data received by the first input terminal and the second input terminal. The diode comprises an anode terminal coupled to a voltage source and a cathode terminal coupled to the first switch and the second switch. The first transistor comprises a first source, a first drain and a first gate. The first source is coupled to the first bit line. The first drain is coupled to the data storage unit, and the first gate is coupled to the word line. The second transistor comprises a second source, a second drain and a second gate. The second source is coupled to the second bit line, the second drain is coupled to the data storage unit, and the second gate is coupled to the word line.

Another embodiment of a memory data reading circuit of the invention comprises, a plurality of word lines, a plurality of pairs of bit lines, a plurality of memory cells, a plurality of amplifiers, a plurality of diodes and a voltage source. The memory cells are arranged in a matrix. The corresponding word line and the corresponding pair of bit lines can access each memory cell. The amplifiers are coupled to the pairs of bit lines to read and amplify the data stored in the cells. The voltage source pre-charges the pairs of bit lines via the diodes.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a conventional memory data reading circuit with a precharging circuit.

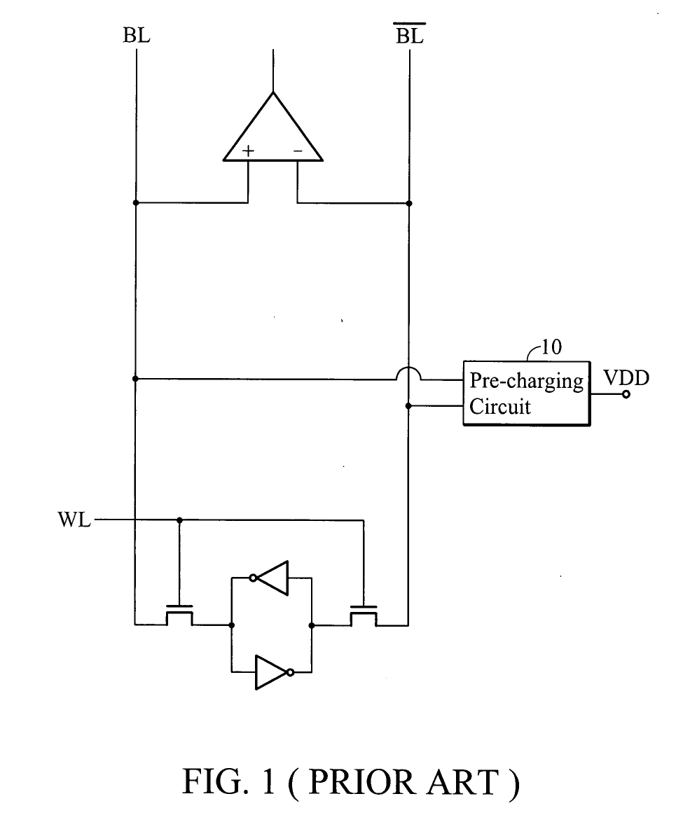

FIG. 2 is a circuit diagram of an embodiment of the memory data reading circuit of the invention.

FIG. 3 is a circuit diagram of a memory data reading circuit of another embodiment of the invention.

FIG. 4 is a circuit diagram of a memory data reading circuit of another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

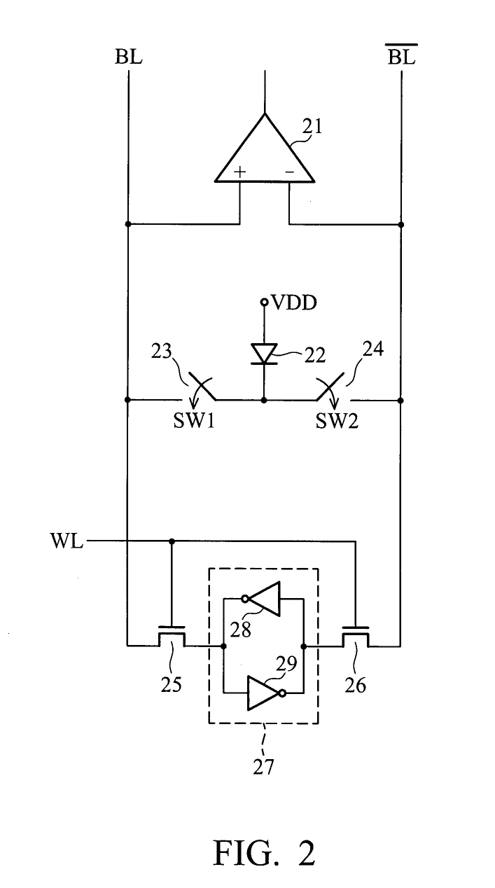

FIG. 2 is a circuit diagram of an embodiment of the memory data reading circuit of the invention. The amplifier 21 has a first input terminal and a second input terminal respectively coupled to a first bit line BL and a second bit line B̅L̅. The first switch 23 is coupled to the first bit line BL and the second switch 24 is coupled to the second bit line B̅L̅. The diode 22 has an anode terminal coupled to a voltage source VDD and a cathode terminal coupled to the first switch 23 and the second switch 24. The voltage source VDD precharges the first bit line BL and the second bit line B̅L̅ by turning on the first switch 23 and the second switch 24 respectively. The first transistor 25 has a first source, a first drain and a first gate. The first source is coupled to the first bit line BL, the first drain is coupled to a data storage unit 27, and the first gate is coupled to a word line WL. The second transistor 26 has a second source, a second drain and a second gate. The second source is coupled to the second bit line B̅L̅, the second drain is coupled to a data storage unit 27, and the second gate is coupled to a word line WL. When the data storage unit 27 is selected, a high voltage is applied via the word line WL to turn on the first transistor 25 and the second transistor 26. The data stored in the data storage unit 27 is transmitted to the amplifier 21 via the first bit line BL and the second bit line B̅L̅. The amplifier 21 outputs data based on the data received from the two input terminals of the amplifier 21. The data storage unit 27 comprises a first inverter 28 having an output terminal coupled to the first drain of the first transistor 25, and a second inverter 29 having an input terminal coupled to the output terminal of the inverter 28 and an output terminal coupled to the second drain of the second transistor 26.

In this embodiment, the operating voltage VDD of the memory is between 1.2V and 1.6V and a voltage drop caused by the diode 22 is between 0.6V and 0.8V approximately.

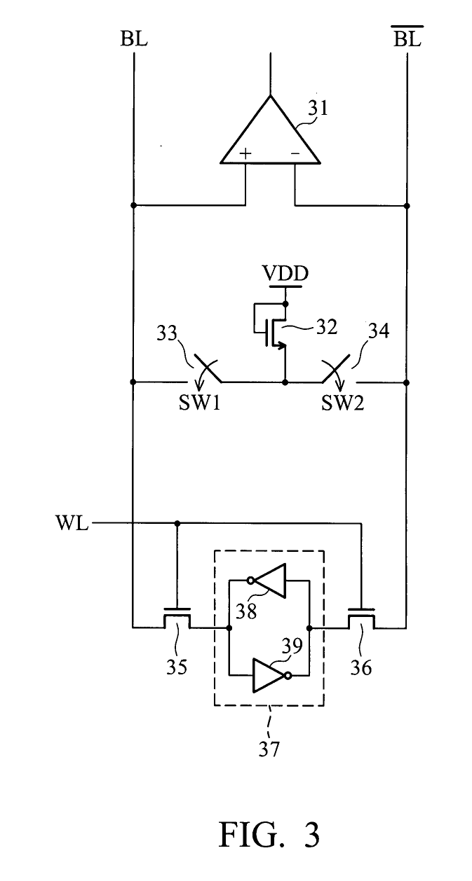

FIG. 3 is a circuit diagram of a memory data reading circuit of another embodiment of the invention. The amplifier 31 has a first input terminal and a second input terminal respectively coupled to a first bit line BL and a second bit line B̅L̅. The first switch 33 is coupled to the first bit line BL and the second switch 34 is coupled to the second bit line B̅L̅. FIG. 3 shows a PN junction diode formed by an NMOS transistor, the gate and drain of which are coupled. The source of the NMOS transistor 32 is coupled to the voltage source VDD and the drain of the NMOS transistor 32 is coupled to the first switch 33 and the second switch 34. The voltage source VDD respectively precharges the first bit line BL and the second bit line B̅L̅ by turning on the first switch 33 and the second switch 34. The first transistor 35 has a first source, a first drain and a first gate. The first source is coupled to the first bit line BL, the first drain is coupled to a data storage unit 37, and the first gate is coupled to a word line WL. The second transistor 36 has a second source, a second drain and a second gate. The second source is coupled to the second bit line B̅L̅, the second drain is coupled to a data storage unit 37, and the second gate is coupled to a word line WL. When the data storage unit 37 is selected, a high voltage is applied via the word line WL to turn on the first transistor 35 and the second transistor 36. The data stored in the data storage unit 37 is transmitted to the amplifier 31 via the first bit line BL and the second bit line B̅L̅. The amplifier 31 outputs data based on the data received from the two input terminals of the amplifier 31. The data storage unit 37 comprises a first inverter 38 having an output terminal coupled to the first drain of the first transistor 35, and a second inverter 39 having an input terminal coupled to the output terminal of the inverter 38 and an output terminal coupled to the second drain of the second transistor 36.

In this embodiment, the operating voltage VDD of the memory is between 1.2V and 1.6V, and a voltage drop caused by the diode formed by the NMOS transistor 32 is between 0.6V and 0.8V approximately.

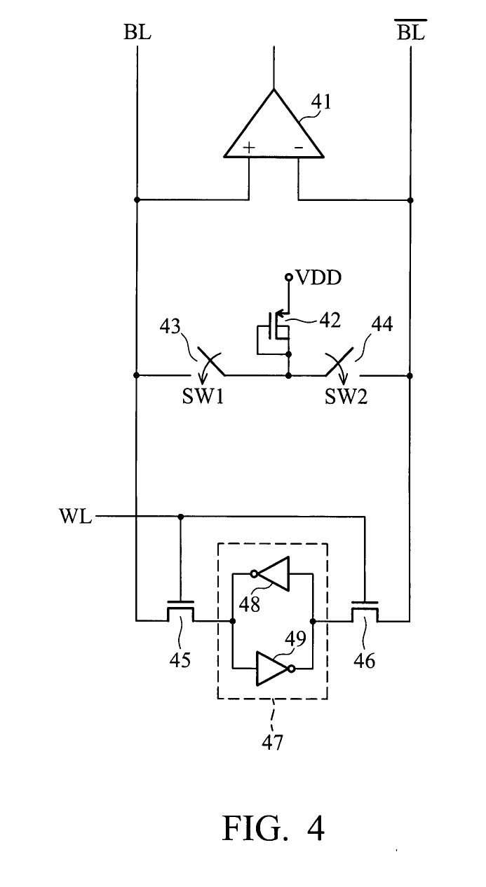

FIG. 4 is a circuit diagram of a memory data reading circuit of another embodiment of the invention. The amplifier 41 has a first input terminal and a second input terminal respectively coupled to a first bit line BL and a second bit line B̅L̅. The first switch 43 is coupled to the first bit line BL and the second switch 44 is coupled to the second bit line B̅L̅. In FIG. 4, the diode is formed by a PMOS transistor, the gate and drain of which are coupled to form a PN junction diode. The source of the PMOS transistor 42 is coupled to the voltage source VDD and the drain of the PMOS transistor 42 is coupled to the first switch 43 and the second switch 44. The voltage source VDD respectively precharges the first bit line BL and the second bit line B̅L̅ by turning on the first switch 43 and the second switch 44. The first transistor 45 comprises a first source, a first drain and a first gate. The first source is coupled to the first bit line BL, the first drain is coupled to a data storage unit 47, and the first gate is coupled to a word line WL. The second transistor 46 has a second source, a second drain and a second gate. The second source is coupled to the second bit line B̅L̅, the second drain is coupled to a data storage unit 47, and the second gate is coupled to a word line WL. When the data storage unit 47 is selected, a high voltage is applied via the word line WL to turn on the first transistor 45 and the second transistor 46, and the data stored in the data storage unit 47 is transmitted to the amplifier 41 via the first bit line BL and the second bit line B̅L̅. The amplifier 41 outputs data based on the data received from the two input terminals of the amplifier 41. The data storage unit 47 comprises a first inverter 48 having an output terminal coupled to the first drain of the first transistor 45, and a second inverter 49 having an input terminal coupled to the output terminal of the inverter 48 and an output terminal coupled to the second drain of the second transistor 46.

In this embodiment, the operating voltage VDD of the memory is between 1.2V and 1.6V, and a voltage drop caused by the diode formed by the PMOS transistor 42 is between 0.6V and 0.8V approximately.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory data reading circuit, comprising:
a first bit line;
a second bit line;
an amplifier having a first input terminal coupled to the first bit line, a second input terminal coupled to the second bit line and an output terminal outputting data based on the data received by the first input terminal and the second input terminal,
a first switch coupled to the first bit line;
a second switch coupled to the second bit line;
a diode having an anode terminal coupled to a voltage source and a cathode terminal coupled to the first switch and the second switch;
a data storage unit;
a word line;
a first transistor having a first source, a first drain and a first gate, wherein the first source is coupled to the first bit line, the first drain is coupled to the data storage unit, and the first gate is coupled to the word line; and
a second transistor having a second source, a second drain and a second gate, wherein the second source is coupled to the second bit line, the second drain is coupled to the data storage unit, and the second gate is coupled to the word line.

2. The circuit as claimed in claim 1, wherein the voltage provided by the voltage source is approximately twice that of a voltage drop caused by the diode.

3. The circuit as claimed in claim 1, wherein a voltage drop caused by the diode is approximately between 0.6V and 0.8V.

4. The circuit as claimed in claim 3, wherein the voltage provided by the voltage source is between 1.2V and 1.6V approximately.

5. The circuit as claimed in claim 1, wherein the diode is formed by a NMOS transistor.

6. The circuit as claimed in claim 1, wherein the diode is formed by a PMOS transistor.

7. A memory, comprising:
a plurality of word lines;
a plurality of pairs of bit lines;
a plurality of memory cells arranged in a matrix, wherein each memory cell can be accessed by the corresponding word line and the corresponding pair of bit lines;
a plurality of amplifiers coupled to the pairs of bit lines to read and amplify the data stored in the cells;
a plurality of diodes coupled to the pairs of bit lines; and
a voltage source for precharging the pairs of bit lines via the diodes.

8. The memory as claimed in claim 7, wherein each pair of bit lines comprises a first bit line and a second bit line, and the diode is coupled to the first bit line and the second line by a first switch and a second switch.

9. The memory as claimed in claim 7, wherein a voltage drop caused by the diode is approximately between 0.6V and 0.8V.

10. The memory as claimed in claim 9, wherein the voltage provided by the voltage source is between 1.2V and 1.6V approximately.

11. The memory as claimed in claim 7, wherein the diode is formed by an NMOS transistor.

12. The memory as claimed in claim 7, wherein the diode is formed by a PMOS transistor.
